(19) United States
(12) Patent Application Publication
(10) Pub. No.: US 2011/0278058 A1
(43) Pub. Date: Nov. 17, 2011

(54) NANOMATERIAL COMPOSITES AND METHODS OF MAKING

(75) Inventors: Uttandaraman Sundararaj, Calgary (CA); Genaro Gelves, Edmonton (CA); Mohammed Al- Saleh, Edmonton (CA)

(73) Assignee: THE GOVERNORS OF THE UNIVERSITY OF ALBERTA, Edmonton, AB (CA)

(21) Appl. No.: 13/146,241

(22) PCT Filed: Feb. 1, 2010
(86) PCT No.: PCT/CA10/00121

§ 371 Date: Aug. 2, 2011

Related U.S. Application Data
(60) Provisional application No. 61/148,554, filed on Jan. 30, 2009.

(51) Int. Cl. H05K 5/00; B29C 43/02; H02G 3/02; H01B 7/00; B82Y 99/00; B82Y 30/00

(52) U.S. Cl. 174/520; 174/68.1; 174/113 R; 174/50; 264/241; 977/762; 977/932

(57) ABSTRACT

There is an electromagnetic interference shield and methods of constructing an electromagnetic interference shield. An electromagnetic interference shield has a network of conductive nanowires dispersed in a matrix material. The conductive nanowires form a segregated network. The segregated network may be a honeycomb network In a method for constructing an electromagnetic interference shield, a composite of conductive nanowires and matrix material is produced. Pockets of matrix material are formed within the composite of nanowires and matrix material. The pockets of matrix material may be formed by precipitation of the matrix material from a solvent or through dry-mixing of the composite with a second matrix material.

### TECHNICAL FIELD

This device and method relate to the field of nanomaterial composites, and in particular, to nanomaterial composites for electromagnetic interference shielding.

### BACKGROUND

Electromagnetic interference (EMI) is the generation of undesired signals in an electrical or electronic device due to the interaction between external electromagnetic radiation and internal electrical signals. Electromagnetic interference (EMI) shielding refers to the ability of materials to prevent electromagnetic radiation to penetrate or be emitted from an electronic device and prevent malfunction of electronic equipment. Protecting electronic devices from incoming EMI is required to maintain devices' functionality and integrity, while controlling electronic devices' EMI emissions is essential in complying with electromagnetic compatibility standards imposed by governmental agencies. The miniaturization of electronics introduces high requirements for EMI shielding and new materials with improved performance are required.

Current technologies available for EMI shielding include: (1) Conductive coatings such as metallic coatings, conductive paints, coatings from vacuum metallizing. Conductive coatings are typically applied on plastic substrates. A conductive coating is typically a thin film (3-4 μm) of pure copper or silver deposited by electroless plating or a relatively thick film (25-75 μm) of a conductive paint (metal or carbon particles in acrylic or urethane polymer matrix) applied by conventional painting process. Electroless plated films exhibit EMI shielding effectiveness (SE) of 70-100 dB, while the EMI SE of film prepared by conductive paint is in the range of 30-90 dB. Although conductive coatings are the most conventional technology for EMI shielding, they have disadvantages such as high cost of manufacturing, multistep manufacturing, leakage of radiation in final products, possibility of delamination and difficulties for recycling. (2) Polymer composites that comprise polymers filled with electrically conductive materials such as stainless steel fibers, Ni-plated C-fibers, Ag-coated glass fibers, Ni-coated graphite. These materials contain fibers with dimensions in the range of microns in diameter, which require high loadings to be effective and affect the processibility of the composite. Conventional conductive polymer composites (CPCs) made of carbon black (CB), carbon fiber (CF), metal coated CF, nickel filaments, or aluminum (Al), copper (Cu) and stainless steel (SS) fibers have been investigated for EMI shielding applications. However, none of the conventional composites are able to significantly penetrate the EMI shielding market because of the high loading of filler required to achieve adequate shielding increase in material cost, weight and processing complexity. EMI SE of a polymer composite depends on the polymer type, polymer viscosity, filler aspect ratio, filler dispersion, filler distribution, filler conductivity, filler magnetic permeability, thickness of the shielding plate and frequency of the electromagnetic (EM) radiation. Therefore, it is difficult to assign the level of filler required to achieve certain EMI SE. For conventional CPCs, the best EMI SE results reported in literature at the lowest filler loading are those for SS/polymer composites. For example, EMI SE of ˜50 dB in the 0.2 GHz-1.5 GHz frequency range was reported for a 1.5 mm thick plate made of 14 wt % (˜2.1 vol %) SS/Acrylonitrile-butadiene-styrene (ABS) composite. To attain the same level of shielding using CF ≧30 vol % CF is typically required.

Other EMI shielding options include metal cabinets and foil laminates. Some emerging technologies for EMI shielding materials include: carbon nanotube-filled polymers, for example those disclosed in PCT/US2006/048165, and intrinsically conductive polymers (ICPs). The low purity, high price of nanotubes, and the diverse range of electrical properties (semiconductor to conductor behavior) have prevented the commercial development of nanotube-based polymers. ICPs such as polyaniline possess limitations such as aging, poor mechanical properties and poor processability.

Because of their low-weight, design flexibility, easy processability and high conductivity at low filler loading, conductive high aspect ratio-nanofiller/polymer composites (CNPCs) are promising advanced materials for EMI shielding in laptops, cell phones, aircraft electronics, etc. Thin, lightweight, and highly electrically conductive polymer composites are desirable for EMI shielding applications. Although these materials are the most promising alternative for EMI shielding, attaining high electrical conductivity and high shielding performance requires high concentrations of conductive fillers, which significantly affects the dimensionality, weight, processability, and mechanical properties of conventional composites. Recently, high aspect ratio conductive nanofillers such as carbon nanotubes (CNTs) and carbon nanofibers (CNFs) have been used to produce CNPCs for EMI shielding. Polymer filled with nano-sized carbon filler has higher EMI shielding at lower filler loadings than polymers filled with conventional micron sized fillers like CFs. CNTs and CNFs have higher conductivity, larger surface area and smaller diameter than CFs. The higher conductivity enhances both the shielding by reflection and by absorption. The larger surface area increases shielding by reflection. Currently, the influence of the nanometer size of these conductive fillers on the EMI SE is not well understood. For micron size fillers, smaller diameter of filler leads to better EMI SE due to the larger volume fraction of the filler contributing in the EM waves shielding by absorption.

The major challenge in formulating a conductive composite with a low percolation threshold, which is the critical concentration at which the first conductive network is built in the matrix, is good dispersion of the nanofiller while retaining the nanofiller aspect ratio. For CNT/Polymer composites, several techniques have been developed to better disperse the nanofiller, including in-situ polymerization, solution processing, spin casting and melt spinning. In addition, some processing aids have been used to enhance the dispersion and/or alignment of nanofillers such as sonication, magnetic fields and surfactants. Functionalization and grafting of nanofiller have also been considered to enhance the dispersion. However, functionalizing the nanowires negatively influences the electrical conductivity of the nanowires and their composites. Typically functional chemicals cover the surface of the nanowires with an insulating layer or multi-layers. Prolonging sonication time is another option but significantly degrades the aspect ratio of the already dispersed nanowires and furthermore, sonication will not disperse the bundles if they were formed by irreversible fusion during the deposition or liberation of nanowires.

Although uniform distribution of dispersed nanofillers is conventionally pursued in much of scientific literature, segregated nanofiller networks enable highly conductive composites at lower nanofiller concentrations. Typically, these types of morphologies in polymer composites have been attained using the double percolation concept in polymer blends on carbon black-based composites or mixing in solid state of polymer and conductive particles. However, new approaches for nanocomposite preparation are required to enable nanofiller network formation in organic polymer matrixes leading to outstanding properties.

Dry mixing and compression molding were previously used to reduce the percolation threshold of microfiller/polymer composites. Results indicated that percolation threshold decreases with decreasing the ratio of filler particle size to polymer particle size, and with increasing the filler aspect ratio. For a polymer powder 100 μm in diameter and metal particles 1-5 micron in diameter, 5-10 vol % filler are required to construct a conductive network in a polymer matrix by dry mixing and compression molding. Capozzi and Gerhardt (“Novel Percolation Mechanism in PMMA Matrix Composites Containing Segregated ITO Nanowire Networks”, Adv. Funct. Mater. 2007, 17, 2515-2521) used a mechanical blender to dry mix indium tin oxide (ITO) nanoparticles having average size of 31 nm with poly(methyl methacrylate) PMMA having particle size distribution of 5-100 μm. The ITO/PMMA composite showed electrical resistivity of 10⁸ Ohm-cm at 0.7 vol % ITO. However, dry mixing of a nanofiller with a polymer powder is difficult.

### SUMMARY

In one embodiment there is an electromagnetic interference shield, comprising a matrix material and a conductive network of nanowires having a segregated distribution of nanowires within the matrix material.

In one embodiment there is a method of manufacturing an electromagnetic interference shield, comprising producing a composition of conductive nanowires and a matrix material, and forming pockets of matrix material in the composition of conductive nanowires and the matrix material to form a conductive network of conductive nanowires within the matrix material.

In one embodiment there is a method of forming an electromagnetic shielding material, comprising (a) forming a mixture of conductive nanowires and a matrix material in a solvent, (b) precipitating matrix material from the solvent to form nanowire composite particles, (c) separating the nanowire composite particles from the solvent and (d) combining the nanowire composite particles into a conductive network composition of nanowire and matrix material.

In one embodiment there is a method of producing a conductive electromagnetic interference shield, comprising producing an initial conductive nanowire composite comprising conductive nanowires and a first matrix material and diluting the initial conductive nanowire composite with a second matrix material.

In one embodiment there is an electromagnetic interference shield, comprising conductive nanowires having a segregated distribution in a matrix material.

In one embodiment there are novel polymer matrix compounds comprising electrically conductive metal nanowires and nonconductive polymers for EMI shielding. The novel composites contain metal nanowires, are lightweight materials, are easier for processing, and provide high EMI shielding effectiveness.

In one embodiment, a solution of polymer in a first solvent is mixed with a mixture, for example a dispersion, of nanowires in a second solvent to form a mixture of polymer and nanowires. The first and second solvents are selected so that the polymer is insoluble in the mixture of polymer and nanowires, the two solvents being miscible. Examples of first and second solvent, respectively, combinations include for example methanol and methylene chloride, ethanol and methylene chloride, ethanol and toluene, and methanol and xylenes. Upon the addition of the nanowire solution to the polymer solution under mixing (for example sonication and mechanical mixing), a suspension of nanowire/polymer nanocomposite may be formed. The mixture is then dried, for example to less than 0.1 wt % solvent, to obtain a powdery composite. A conductive composite product may then be obtained by suitable methods for example at least one of melt-mixing (such as extrusion, injection molding and mixing in batch mixers), rotational molding, in-situ polymerization, coagulation, wet mixing, dry mixing (Composite powder+polymer powder), solution processing, and preferably compression molding. The composite product may also be made by dissolution of the nanowire/polymer powder in a solvent or solvent mixture, and then applying this coating on surfaces by typical coating techniques (spin coating, spray coating, dip coating).

In one embodiment, a conductive powder composite of polymer and nanowires is dry-mixed with powdered polymer, and the mixture is then compression molded into a conductive composite product, for example a film or plate. By using dry-mixing followed by compression molding, the electrical resistivity and EMI SE are reproducibly controlled and electrical percolation threshold reduced. The initial conductive powder composite may be made by suitable methods, such as the method disclosed above. In one embodiment dry refers to a solvent concentration of less than 0.1 wt %.

These and other aspects of the device and method are set out in the claims, which are incorporated here by reference.

### BRIEF DESCRIPTION OF THE FIGURES

Embodiments will now be described with reference to the figures, in which like reference characters denote like elements, by way of example, and in which:

FIG. 1A is a section view of a nanowire composite;

FIG. 1B is a perspective view of an electromagnetic interference shield;

FIG. 2 is a flow diagram representing a method of manufacturing an electromagnetic interference shield through forming pockets of matrix material;

FIG. 3 is a flow diagram showing a method of forming an electromagnetic shielding material through precipitation;

FIG. 4A is a section view of a solvent containing nanowires and matrix material;

FIG. 4B is a section view of a nanowire composite particle in a solvent;

FIG. 4C is a section view of a nanowire composite particle;

FIG. 4D is a section view of a collection of nanowire composite particles;

FIG. 5A is a perspective view of a copper nanowire polystyrene nanowire composite particle;

FIG. 5B is a plan view of a collection of nanowire composite particles in a compression mold;

FIG. 6 is a flow diagram representing a method of forming an electromagnetic interference shield through dilution;

FIG. 7 is a section view of a segregated nanowire network in a matrix material;

FIG. 8 is a plan view of a device having an electromagnetic interference shield;

FIG. 9 is a plan view of a device having an electromagnetic interference shield;

FIG. 10 is a plan view of a collection of nanowires in a matrix material with bad distribution and bad dispersion;

FIG. 11 is a plan view of a collection of nanowires in a matrix material with good distribution and bad dispersion;

FIG. 12 is a plan view of a collection of nanowires in a matrix material with bad distribution and good dispersion; and

FIG. 13 is a plan view of a collection of nanowires in a matrix material with good distribution and good dispersion.

### DETAILED DESCRIPTION

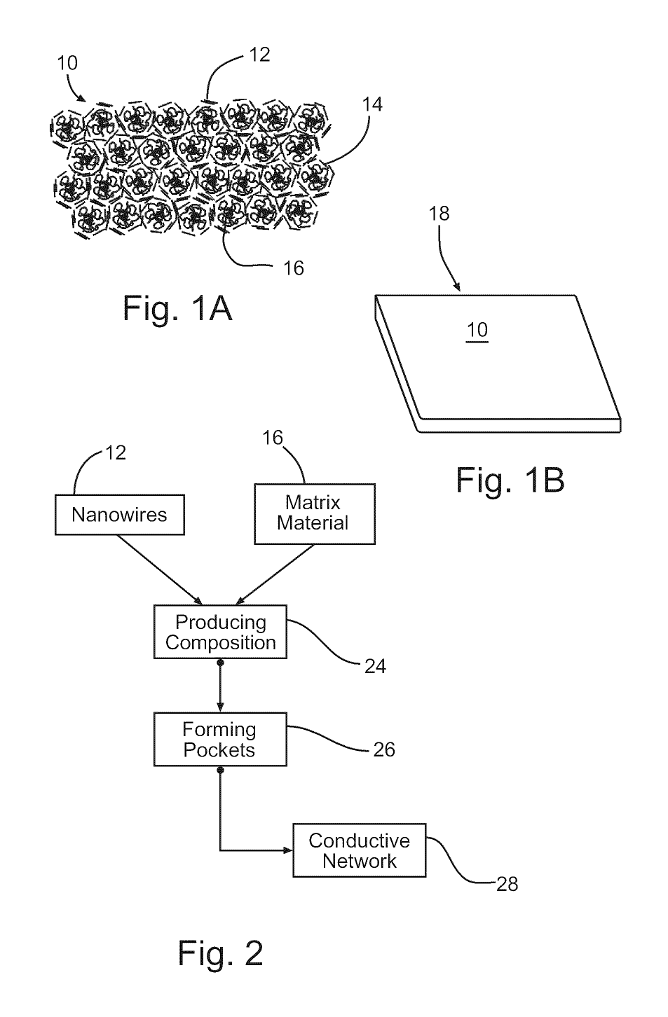

FIG. 1A shows an electromagnetic interference shield 10 for electromagnetic interference shielding. The electromagnetic interference shield 10 is a nanowire composite. A collection of conductive nanowires 12 form a conductive network of nanowires 14 within a matrix material 16. The nanowires 12 have a segregated distribution within the matrix material 16. In FIG. 1A, the nanowires 12 form a honeycomb structure 20. FIG. 1B shows a section of nanowire composite 10 forming an electromagnetic interference shielding sheet 18.

FIG. 2 is a flow diagram representing a method of manufacturing an electromagnetic interference shield. A composition of conductive nanowires is produced 24 which is composed of conductive nanowires 12 and a matrix material 16. Pockets of matrix material are formed in the composition of conductive nanowires and the matrix material at 26 to form a conductive network 28 of conductive nanowires within the matrix material, such as shown in FIG. 1A. The pockets of matrix material may be produced by various methods, including for example, (a) by precipitation of the matrix material from a solution or (b) by dry-mixing additional matrix material into the composition.

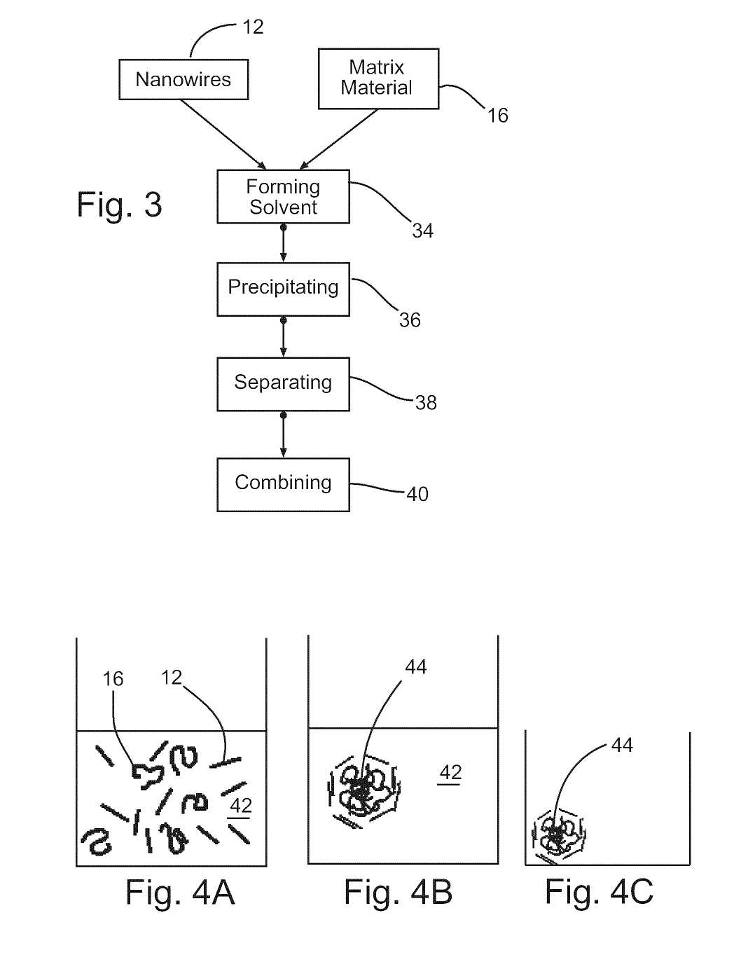

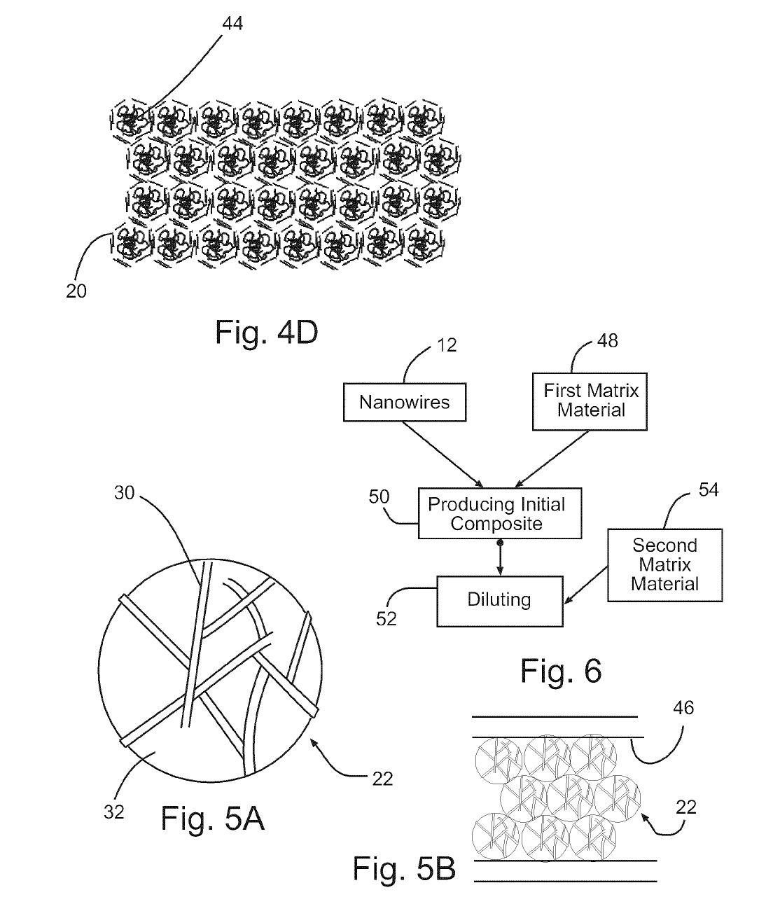

FIG. 3 is a flow diagram showing a method of forming an electromagnetic shielding material. FIGS. 4A-4D represent the various stages of production of the method shown in FIG. 3. At 34, the mixture of conductive nanowires 12 and a matrix material 16 is formed in a solvent 42. At 36, matrix material is precipitated from the solvent to form nanowire composite particles 44. At 38, the nanowire composite particles are separated from the solvent 42. At 40, the nanowire composite particles are combined into a conductive network composition of nanowire and matrix material 16. The nanowire composite particles 44 are combined to create a honeycomb structure 20.

In one embodiment, the method shown in FIG. 3 employs a Miscible Solvent Mixing and Precipitation (MSMP) method to prepare nanowire/polymer nanocomposites. In this embodiment the matrix material 16 may be a polymer. The method consists of mixing at step 34 nanowire suspensions and polymer solutions in a miscible solvent mixture in which the nanowire suspensions are made of a poor solvent for the polymer of interest; the non-solvent/solvent ratio of the mixture is then modified to decrease the solubility of the polymer, leading to polymer nanocomposite precipitation as shown in FIG. 3 at step 36. This method enables the formation of nanocomposite particles with unique and useful morphologies of interconnected nanowires within the polymer matrix. The nanocomposite particles can be easily separated from the solvent mixture by solid-liquid separation techniques and further processed by techniques like compression molding, injection molding, melt processing, and masterbatching.

In one embodiment, the conductive nanowire 12 may be copper nanowire (CuNW) and the matrix material 16 may be polystyrene (PS). The CuNW/PS nanocomposites for EMI shielding may be further processed using compression molding. CuNW/PS samples after MSMP were embedded in epoxy and then ultramicrotomed in 70 nm thick sections. The CuNWs preferentially form segregated structures around polymer phases. Nanocomposite particles were introduced in a compression mold and hot-pressed at 250° C. and 31 MPa for 30 minutes to obtain specimens for electrical and EMI shielding characterization. The segregated structures observed in the nanocomposite particles remain after the compression molding step. CuNWs are preferentially located around polymer nuclei formed during the precipitation step of the MSMP method. The distribution of the nanowires leads to a honeycomb structure 20 as shown in FIG. 4D. The honeycomb structure 20 enables the reduction of the electrical percolation threshold since a lower amount of nanowires is required to form a conductive network compared to when the nanowires are uniformly distributed in a polymer matrix.

Surface modification of CuNWs and use of surfactants is unnecessary and may be avoided in order to prevent the formation of electron barriers and achieve the highest electrical conductivity and EMI shielding performance. Segregation of CuNWs is a result of weak interaction between the nanowire surface and polymer chains. Once the volume fraction of non-solvent, for example CH₃OH, is increased and the miscible mixture, for example CH₃OH/CH₂Cl₂, reaches a critical solvent ratio (i.e. cloud point), PS chains retract and thus reduce the surface area of interaction with the non-solvent; nucleation and growth of PS rich regions is initiated. Weak surficial interaction between CuNWs and PS prevents significant incorporation of nanowires within the polymer nuclei (i.e. if attraction forces between CuNWs and PS were dominant, the nanowires would be more significantly incorporated in the polymer precipitate and will be randomly distributed). CuNWs are primarily located around the polymer nuclei during precipitation due to dominant van der Waals forces between nanowires. When the polymer is melted during compression molding, the relatively low shear of the process keeps the nanowires on the surface from being dispersed into the PS phase thus creating nanowire honeycomb networks 20 (FIG. 4D). The nanowires come to close contact after compression molding and lead to highly conductive composites at low nanowire concentration.

FIG. 5A shows a precipitated polymer nucleus 32 which forms a nanowire composite particle, 22 of CuNW/PS nanocomposites obtained from miscible solvent mixing and precipitation (MSP) method. The particles 22 may grow several microns in size and contain nanowires 30 primarily distributed on the particle surface.

The miscible solvent mixing and precipitation method enables the formation of unique nanowire networks in a single polymer phase. This approach does not require surfactants or nanoparticle surface modification and can be applied to produce a wide range of conductive polymer nanocomposites. The resulting metal nanowire/polymer nanocomposites are lightweight, thin, and highly electrically conductive. The EMI SE exhibited by CuNW/PS nanocomposites containing nanowire honeycomb networks exceed that of emerging CNT/polymer composites. CuNWs may be used to prepare CuNW/PS nanocomposites.

CuNW/PS nanocomposites obtained from the MSMP method have nanowires preferentially localized at the surface rather than randomly distributed in the particle 22 (FIG. 5A). CuNWs are localized around the polymer phase forming segregated networks because of weak nanowire-polymer attraction forces. The nanowires at several particle surfaces form networks when the particles are close to each other. Polymer nanocomposite particles were further processed by compression molding to prepare specimens for EMI shielding characterization as shown in FIG. 5B. The nanowire composite particles 22 are compressed in a compression mold 46. The structures in the particles of nanowires remain after compression molding and CuNWs form a percolated segregated network throughout the specimen (as shown in FIG. 4D). The nanowire networks formed by MSMP method reach electrical contact and enable high electrical conductivity and high EMI shielding effectiveness.

FIG. 6 is a flow diagram representing a method of producing a conductive electromagnetic interference shield. At 50, an initial conductive nanowire composite is produced. The conductive nanowire composite comprises conductive nanowires 12 and a first matrix material 48. At 52, the initial conductive nanowire composite is diluted with a second matrix material 54. The first and second matrix materials 48 and 54 may be comprised of the same material.

In one embodiment, the initial conductive nanowire composite is CuNW/PS composite powder. The second matrix material 54 is pure PS powder. The dilution of the initial conductive nanowire composite is achieved by dry-mixing composites of highly conductive CuNW/PS composite powder (CNCP) with pure PS powder. The dry mixing may be performed in a mortar. The CNCP powder may, for example, be formulated by adding 150 ml of 3.33 mg CuNW/ml methanol solution to 75 ml solution of 28.6 mg PS/ml methylene chloride and processing the mixture using solution processing. Henceforth, we will refer to the composites prepared by mixing CNCP with PS powder as CNCP/PS composites, while the designation CuNW/PS will be used to refer to the composites prepared by solution processing.

Compression molding may be used to form conductive nanowire polymer composites from composite powders, the compression molding applied being greater than 9 MPa and preferably in the range of 24-47 MPa. High compression molding pressures (>24 MPa) should be used to produce a composite with high electrical conductivity and high EMI shielding effectiveness at low filler loading. It is believed that the extra pressure brings the nanowires into contact (leads to formation of more conductive networks), and destroys/removes any oxide layers that might exist at the surface of nanowires, for example Cu oxide.

For EMI SE, electrical resistivity and composite morphology characterization, dry-mixed and solution processed composites may, for example, be annealed in the Carver compression molder at 250° C., 31 MPa for 30 min to produce films 210 μm in thickness, 2.5 cm in width and 4.2 cm in length. The mold used may, for example, consist of 2 stainless steel plates, 2 sheets of fiber glass filled Teflon covering the inner faces of the SS plates and SS plate having 4 cavities each one have the above motioned dimensions.

In one embodiment the composites have nanowires dispersed throughout the composites such that the nanowires form a 3D network spanning the sides of the composite product preferably without being homogeneously well distributed. In this segregated distribution, the nanowires are dispersed throughout the composite while being non-uniformly distributed to form a network that spans the composite. This dispersion may be achieved with nanowire volume percentages of for example 0-15% with preferably concentration below 1.5%, for example between 0.2 and 1.0%. Higher concentrations give better EMI shielding results, but concentrations below 1.5% produce products with good EMI SE properties for a lower cost. Further, this dispersion may also be achieved with films between for example 0.2 mm and 0.9 mm. The novel composites have lower percolation thresholds, higher EMI SE, and lower concentrations of nanowires than previous EMI SE materials. Lower filler volume fractions allow the composite to retain the polymer properties such as ductility, and facilitate composite processability and color-ability. The composites have much higher EMI SE than known composites for example for CNT polymer composites. Such high EMI SE makes the composite favorable in advanced applications such as in the military, in which EMI SE exceeding 50 dB is required. Lower shielding requirements can be satisfied using a lower filler concentration.

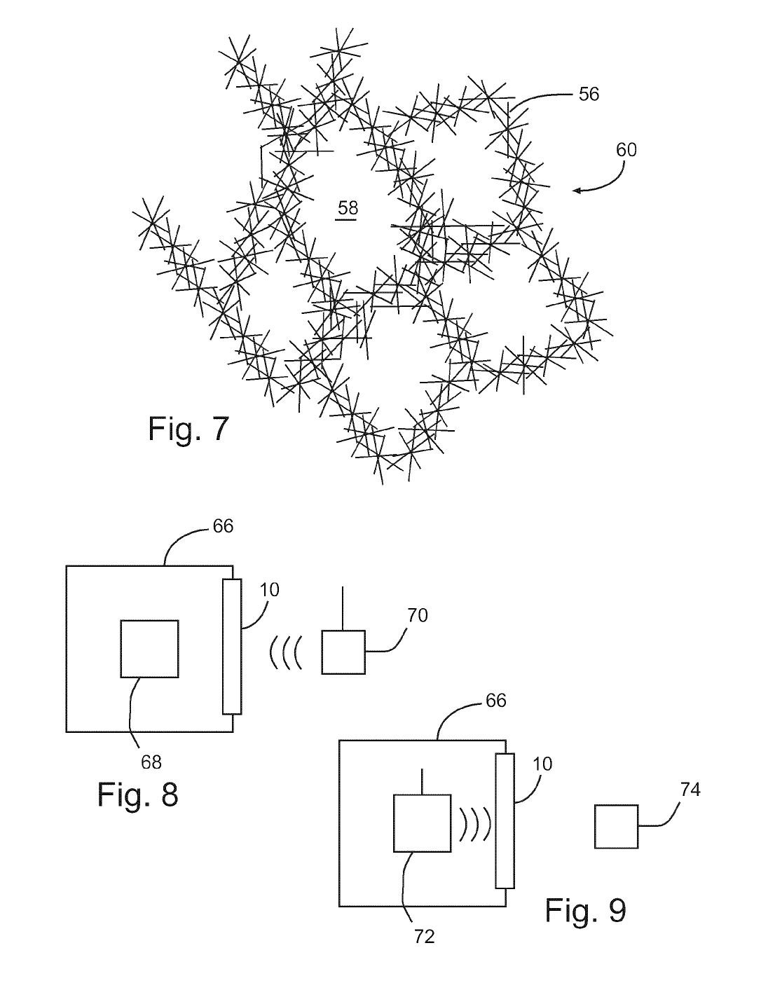

FIG. 7 shows CNCP/PS composites prepared by dry mixing followed by compression molding. Pockets of the matrix material polystyrene 58 are interspersed within a network of CuNWs 56, which form a conductive network of nanowires 60. The size of the network decreases with decreasing CNCP concentration. The CNCP phase is seen to have irregular shapes. In fact, such irregular structures facilitate the formation of conductive networks at lower concentrations. With concentrations as low as 15/85 CNCP/PS composite, which corresponds to 0.4 vol % CuNW in PS, a conductive networks is formed by the CNCP, highlighting the advantage of this process; namely mixing conductive powder made of conductive composite with pure polymer powder forms conductive networks at very low filler concentration.

FIG. 8 shows a potential application of the electromagnetic interference shield 10. A housing 66 contains an electronic device 68. The electromagnetic interference shield 10 is supported by the housing 66 and separates the electronic device 68 from an external EMI source 70. The EMI source 70 may be any source of electromagnetic radiation that may interfere with the electronic device 68. The electromagnetic interference shield 10 is adjacent to the electromagnetically sensitive electronic device 68. Protecting an electronic device 68 from an external source of EMI is important to maintain the devices' functionality and integrity.

FIG. 9 shows a potential application of the electromagnetic interference shield 10. A housing 66 contains an internal EMI source 72. The electronic interference shield 10 is supported by the housing 66 and separates the internal EMI source 72 from an external electronic device 74. The electromagnetic interference shield 10 is adjacent to the source of electromagnetic radiation source 72. The electronic interference shield 10 prevents electromagnetic radiation from the internal EMI source 72 from interfering with the external electronic device 74. The source of electromagnetic radiation 72 is disposed within the housing 66. Protecting external electronic devices from internal EMI sources may be required comply with electromagnetic compatibility standards imposed by governmental agencies. The external electronic device 74 may be any piece of electronic equipment that may be sensitive to electromagnetic interference produced by the internal EMI source 72.

The electronic device 68 may itself also be an internal EMI source. Similarly, the internal EMI source 72 may be an electronic device. The electronic device 68 may be, for example, a laptop processor, a cell phone, a handheld device, a printed circuit board, an electronic clothing tag, a component of an aircraft electronic, a medical device or a component of military equipment. The electronic interference shield 10 may find applications in for example electronics, aerospace and the military, and any application in which the protection of components sensitive to electromagnetic radiation is required. Examples of potential products include for example housings for cell phones, hand held devices, computer housings, printed circuit boards, and medical equipment. Composites disclosed herein may be used by for example by laptop manufacturers, mobile phone manufacturers, military and defense industry, medical applications, clothing, and the electronic housing industry. In certain applications, the electromagnetic interference may be microwave radiation (0.3-300 GHz), and may, for example, be interference in the X-band range of frequency (8.2-12.4 GHz).

### Percolation Thresholds

At a critical concentration of filler, which is known as the electrical percolation threshold, the electrical conductivity of composite suddenly increases by several orders of magnitude. Often, at the percolation threshold, the filler forms a continuous network inside the polymer matrix, and creates a conductive composite. Increasing the filler loading further usually has little effect on the composite electrical conductivity. Percolation threshold of polymer composites depends on many factors including filler aspect ratio, filler dispersion, filler distribution, filler conductivity, polymer matrix crystallinity and polymer matrix surface tension. CuNWs are high aspect ratio conductive fillers. Thus, they are able to percolate systems at low filler volume fraction (<<1 vol %). Reducing percolation threshold in high aspect ratio nanofiller/polymer composites is crucial to enhance the composites economic feasibility, since high aspect ratio conductive nanofillers are very costly compared to polymer matrixes. A power law equation derived from the percolation theory is often used to find the percolation threshold concentration. The power law equation uses the electrical resistivity data above the percolation threshold to predict the percolation threshold concentration:

ρ=ρ₀(ν−ν_{C})^{-t}

where ρ is the composite electrical resistivity, ρ₀ is as scaling factor, ν is the volume fraction of filler, ν_{C} is the filler critical volume fraction at the percolation threshold and t is a critical exponent revealing the lattice dimensionality. For systems with spherical particles, the t value is typically 1.9, while it is higher than 2 for fiber-filled systems because fibers have higher aspect ratio than spheres. For many systems filled with 1D nanofillers, at value around 3 was reported. The critical exponent is a useful tool that can reveal information about the dispersion of 1D filler. Low t values (below 1.5) may indicate that conductivity in 1D filler/polymer composite might be due to contact between agglomerates that are spherical in shape, whereas high t values (around 3) may reveal that conductivity is due to contact between individual fibers.

At critical CuNW concentration between 0.6 vol % and 0.8 vol %, there is a sudden and sharp decrease of 12 orders of magnitude in the electrical resistivity. The sudden decrease indicates the formation of a nanowire network or networks. Below the percolation threshold, the composite's electrical resistivity is similar to that of unfilled polymer because the nanowires are apart from each other and not touching. Above 0.8 vol % CuNW, there is a gradual decrease in the electrical resistivity with increase in CuNW content. Numerically, the electrical resistivity decreased 3 orders of magnitude from 10¹ to 10⁴ S·m⁻¹ with increase in CuNW concentration from 0.8 vol % to 2.8 vol %, respectively. Though this decrease is significant, it is smaller than the drop in resistivity between 0.6 to 0.8 vol % CuNW.

The percolation threshold (ν_{C}) and critical exponent (t) of the CuNW/PS composites are 0.67 vol % and 2.9, respectively. The percolation threshold of CuNW/PS composites is very low and within the range of percolation thresholds reported in literature for polymer composites filled with CNTs. However, at concentrations beyond the percolation threshold, the electrical resistivity of the CuNW/PS composites is lower than that of CNTs/polymer composites owing to the lower resistivity of CuNW compared to CNTs. The critical exponent is 2.9; this is an indication of good dispersion of the nanowires with individual nanowires touching each other. The t value depends on the filler geometry and filler dispersion within the polymer matrix. Several CNF and CNT/polymer composites were also found to have at value around 3. In previous work, the electrical resistivity of percolated CuNW/PS composites filled with up to 4 vol % CuNW were found to level out ˜10⁶ Ohm-cm. This electrical resistivity is very high and does not reflect the electrical resistivity of copper. For CuNW/PS formed by dry-mixing, the electrical resistivity of CuNW/PS composites filled with 1.5-2.9 vol % CuNW is the range of 10⁻¹-10⁻² Ohm-cm. The compression molding pressure in previous work was not enough to bring the nanowires into contact and/or to destruct the layers of copper oxide that might have been formed at the nanowires surface. Previously applied pressure was 1.5-2 metric tons, however in this work, the applied pressure was 6.7 metric tons. For CuNW/PS formed through precipitation, nanocomposites containing 1.5-2.8 vol. % CuNWs show p in the range of 10³-10⁴ S·m⁻¹. The nanowire honeycomb network resulting from the MSMP method and compression molding conditions used (31 MPa) result in bringing the nanowires into electrical contact.

Typical percolation behavior is observed, i.e., at a critical nanowire loading, between 0.1 and 0.25 vol %, the composites electrical resistivity decreased by several orders of magnitude indicating the formation of the first conductive network. Interestingly, the percolation curve also shows a significant decrease in the composites electrical resistivity with increase in nanowire concentration from the percolation threshold concentration to 1.3 vol % CuNW. In this zone, i.e. between 0.25 vol % and 1.3 vol % CuNW, the electrical resistivity decreased by 7 orders of magnitude. The remarkable decrease in the electrical resistivity with a small increase in filler content means that the three dimensional conductive network has not yet been formed at the percolation concentration, and thus the composite conductivity is due to tunneling in addition to direct contact between the nanowire particles. Increasing the CuNW concentration beyond 1.3 vol % has a little influence on the composites resistivity.

The percolation threshold concentration and the lattice dimensionality exponent (t) are 0.24 vol % and 2.8, respectively. The 0.24 vol % percolation threshold is lower than those reported for CuNW/PS composites prepared by solution processing (0.5 vol %) and melt mixing (2 vol %). The low percolation threshold reported in this work is related to the segregated structure formed by the CNCP in the PS matrix, the small sizes of the CNCP and the non-spherical shape of the CNCP particles. Moreover, the high t value might indicate that the CNCP particles are behaving like a high aspect ratio filler.

EMI SE is a measure of the material's ability to attenuate the intensity of EM waves. The higher is the SE value, the better is the attenuation. EMI SE is expressed in decibels (dB). For an EM radiation of specific power, EMI SE is the logarithm of the ratio of transmitted power when there is no shield (P₁) to the transmitted power when there is a shield (P₂), SE=10 log(P₁/P₂). Transmitted power when there is no shielding material is typically equal to the incident power. A shielding effectiveness of 20 means that 99% of the EM waves have been blocked; 30 dB corresponds to 99.9%. This level of blocking is considered an adequate shielding for many applications such as notebook and desktop computers.

For CuNW/PS composite films with 210 μm in thickness, EMI SE is independent of the EM radiation frequency in the X-band range. EMI SE of CuNW/PS composites increased with increase in CuNW concentration. For instance, EMI SE increased from 6.5 dB to 42 dB with increasing CuNW concentration from 0.8 to 1.8 vol %. In general, the level of shielding obtained with composites filled with greater than 1 vol % CuNW is suitable for computers and servers shielding applications. For more advanced applications, like medical and military equipments, where a higher level of shielding is necessary, thicker films can be used to attain a SE close to 100 dB.

For CNCP/PS composite films (210 μm in thickness) in the X-band frequency range the EMI SE of the master batch (2.9 vol % CuNW/PS composite) was higher than the dynamic range (>50 dB) of the set-up used. The composite films exhibit outstanding EMI SE at low nanowire concentration. For example, the EMI SE of the (50/50) CNCP/PS composite containing 1.3 vol % CuNW is 27 dB, corresponding to 99.8% blocking of the EMI waves. EMI SE is seen to increase with increase in CuNW concentration, and over the range of frequencies studied; shielding is fairly independent of frequency. Compared to the composites prepared by solution processing, dry-mixed composites have remarkably higher EMI SE at CuNW below 1 vol %. However, at higher CuNW concentrations, EMI SE of solution processed composites is higher than dry mixed composites. For example, the EMI SE of 1.8 vol % CuNW/PS composite prepared by solution processing is 42 dB, while the EMI SE 2.1 vol % CuNW CNCP/PS composite is 36 dB.

The level of EMI SE obtained by the CuNW/PS and CNCP/PS composite films is outstanding compared to those obtained using CNT, MWNT and SWNT. It is apparent that in order to achieve an EMI SE of 26 dB, 1 mm thick plate made of 7 wt % (−4 vol %) CNT filled PS composites is required. However, the same level of shielding can be obtained from a 0.21 mm film (5 times thinner) made of 1-1.3 vol % CuNW/PS composites (3-4 times lower concentration).

For CuNW/PS produced by the MSMP method, EMI SE increased from 6 dB to 38 dB with an increase in CuNW concentration from 0.8 to 1.8 vol. %. The EMI SE of samples with concentrations higher than 2.0 vol. % CuNWs were beyond the dynamic range of the characterization equipment (50 dB). CuNW-based polymer nanocomposites containing segregated nanowire networks will be suitable for several advanced applications, like medical and military equipment, where a higher level of shielding is necessary (typically ˜100 dB). The EMI SE of CuNW/PS nanocomposites is outstanding compared to those previously reported with other emerging filled-polymers containing vapor grown carbon nanofibers (VGCNF), multi-walled (MWCNT) and single-walled (SWCNT) carbon nanotubes. For instance, in order to achieve an EMI SE of 26 dB, 1 mm thick specimens made of ˜4 vol. % MWCNT/PS composites would be required. However, the same level of shielding is obtained using a 0.21 mm film (5 times thinner) made of 1.0-1.3 vol. % CuNW/PS (3-4 times lower concentration). Therefore, the total volume of CuNWs required is about one-twentieth ( 1/20) of that of MWCNTs.

For commercial applications, it is recommended that a material provides at least 20 dB shielding effectiveness (SE), which means that 99% of the wave is attenuated. EMI SE of ˜20 dB have been obtained for the X-band range of frequency (8.2-12.4 GHz) from samples containing only 0.6 vol. % of CuNWs and 0.55 mm in thickness. In addition, CuNW/PS nanocomposites with thickness of only 0.21 mm show outstanding EMI performance compared to thicker materials (1.0-5.5 mm thickness) containing higher filler concentrations. The amount of energy absorbed by a filler is related to the filler skin depth. Skin depth is defined as the depth into the conductive material at which the electric field drops to (1/e) of the incident value. This means that when large-diameter filler is used, only the outer layer of the filler contributes to the EMI shielding. For example, at 1 GHz, the skin depth of copper is 2.1 μm.

The EMI compounds presented for this device and method comprise novel electrically-conductive metal nanowires dispersed in non-conductive polymers. Metal nanowires with high aspect ratios (25 nm in diameter and several microns in length) can form electrically conductive networks at lower concentrations than conventional fibers. Low concentrations of nanowires result in compounds with high EMI shielding effectiveness, improved processability and light weight.

### EMI Shielding Mechanism

Three mechanisms are involved in EMI shielding, namely: reflection, absorption and multiple reflections. In most cases, multiple-reflections adversely affect the overall EMI SE. For CNT/polymer composites, absorption is the primary shielding mechanism; followed by reflection. In order to find the EMI shielding mechanism of the CuNW/PS and CNCP/PS composites, the contribution of reflection versus that of absorption was quantified. The multiple-reflections effect was ignored because it cannot be quantified as a separate factor, and because its influence appears indirectly in the reflection and absorption shielding factors. The EMI SE characterization set-up used measures the transmitted power (T) and reflected power (R) directly. Given that the incident power (I) is known (1 mW), the absorbed power (A) can be calculated using the following equation:

I=T+A+R (1.1)

The sum of the reflected, absorbed and transmitted powers should be equal to the incident power as given in the equation (1.1). It is apparent that amount of power blocked by reflection increased with increase in CuNW loading, i.e. the decrease in composite's resistivity, whereas the amount of power blocked by absorption decreased with increase in CuNW content. For example, for the (75/25) CNCP/PS composite containing 2.1 vol % CuNW, the reflected power is 0.975 mW and absorbed power is 0.025 mW. Such observations have been wrongly interpreted by many researchers to conclude that reflection is the dominant shielding mechanism in CNT/polymer composites. In reality, the lower amount of power blocked by absorption is due to the lower power that enters the sample as a result of better reflection. Contribution of absorption to the overall shielding should be based on the material's ability in attenuating the power that has not been attenuated by reflection.

Regardless of the nanowires loading and composite preparation method, shielding by absorption is higher than shielding by reflection. For the composites prepared by solution processing, the contribution of absorption to the overall shielding is 65%. For composites prepared by dry mixing, shielding by absorption comprise 55% of the overall EMI SE. This indicates that reflection is not the dominant shielding mechanism. In addition, shielding by absorption would be even more important with increase in the thickness of CuNW/PS composite films.

The experimental absorption shielding (SE_{A}) is higher than the theoretical predictions for pure copper films having a relative conductivity equal to 0.1, while it is lower than that of pure copper films with conductivity similar to bulk copper. Because of their small diameter, CuNWs are expected to have lower electrical conductivity than that of bulk copper. Specific electrical resistivity of 1.71×10⁻⁵ Ohm-cm at room temperature has been reported for a copper nanowire 60 nm in diameter and 2.4 μm in length prepared in polycarbonate etched ion-track membrane. The best agreement between the experimental and modeling results was obtained using copper films having a relative conductivity of 0.27.

For the reflection shielding (SE_{R}), theoretical predictions for pure copper films having relative conductivity of 1 and 0.1 are 69 and 59 dB, respectively. These numbers are much higher that the SE_{R} of CuNW/PS composite films. The difference between the composite films SE_{R} and pure copper films SE_{R} decreases with increase in CuNW concentration. This indicates that increasing the concentration of nanowires at the external surface of the hot molded samples enhances the SE_{R}. CuNW/PS composites have extremely high surface area for reflection compared to the pure copper films. Nevertheless, the contribution of this surface area in enhancing the shielding has not been observed and utilized yet. The same applies to CNTs, where contribution of reflection to the overall shielding is below expectations.

EMI SE of 1 mm thick composite plates containing greater than 1 vol % CuNW were above the dynamic range of the EMI SE characterization machine. The experimental shielding by reflection and theoretical shielding by absorption were used to estimate the overall shielding of 1 mm thick CuNW/PS composite plates. Shielding by reflection is independent of sample thickness, so experimental SE_{R} of 210 μm films should be the same as that for 1 mm thick plates. However, shielding by absorption is function of material thickness. Therefore, Shielding due to absorption in 1 mm thick plates was estimated by calculating the SE_{A} of pure copper films having thickness equivalent to the thickness of the nanowires in the PS composite plate and relative conductivity equal to 0.27. It is estimated that 1 mm thick plate made of 1.5 vol % CuNW/PS composite might exhibit an EMI SE of 100 dB. This level of shielding is extremely high and close to levels of shielding obtained using electroless plating processes.

CuNW/polymer composites can be effectively used in advanced applications requiring shielding of EMI. At the same filler volume loading, the EMI SE of the CuNW/PS composites greatly exceeds that of CNT/polymer composites. The EMI SE results showed that in the X-band frequency range, a 210 μm film made of PS composite containing 1.3 vol % CuNW has an EMI SE of 27 dB. For 210 μm samples with EMI SE above 20 dB, contribution of absorption in the overall shielding was higher than that of reflection. The conductivity and thickness of the shielding material determines which shielding mechanism is more important. The importance of absorption increases with increase in sample thickness. The EMI SE was found to increase with increase in CuNW content due to the increase in shielding by absorption and reflection. Theoretical estimations predicted a 100 dB EMI SE of 1 mm plate made of 1.5 vol % CuNW/PS composite.

Dry mixing of a conductive powder made of conductive composite with a polymer powder facilitates the formation of a conductive network at lower filler content. For CNCP/PS composite films, only 0.24 vol % CuNW may be required to construct a segregated conductive network.

In various embodiments described in this document, copper nanowires have been used as an example of the conductive nanowires 12. However, the conductive nanowires 12 may be made of any suitable material, for example ICP fibers, copper, silver, iron, nickel, gold, platinum, palladium, aluminum, zinc, conductive metal oxides (such as tin oxide, indium-tin oxide, antimony-tin oxide, doped-zinc oxide) and metal alloys and/or conductive mixes of metal and other materials. The nanowires may comprise nanowires of several aspect ratios and different metals. Other conductive nanofillers and nanotubes such as vapor grown carbon nanofiber may also be used.

In various embodiments described in this document, polystyrene has been used as an example of the matrix material 16. However, the matrix material 16 may be any substance that allows the nanowires to form a network within the material, such as polymers. The polymers used can be for example polystyrene, polycarbonate, acrylonitrile butadiene styrene, polyimide, epoxies, polyethylene, polypropylene, thermoplastic elastomers, photo or thermal curable polymers, polyesters, polysulfones, polysulfides, polyamides, any suitable blends of polymers, any di-block and tri-block copolymer such as SB, SBS, SEP, SMMA.

A nanowire is a nanostructure with the diameter of the order of a nanometer (10⁻⁹ meters) and for example would be satisfied by a nanostructure with a diameter less than 100 nm. For example, individual CuNWs may be 25 nm in diameter with an average length of 1.29 μm.

CuNW-Filled PS formulation

CuNW-filled PS composites may be formulated using solution processing. The composites by solution processing may, for example, be produced by mixing certain volumes of ˜3.3 mg/ml CuNW/methanol solution with 28.5 mg/ml or 20 mg/ml PS/methylene chloride solution. The mixture may be sonicated for 10 min in a sonicator having an output power of 120 W. The sonicated mixture may then be placed in an evaporation dish for 16 hours. After that, the evaporation dish may be put in a vacuum oven for 2 hr at 40° C. to remove all remaining solvents from the composite powder.

### Segregated Structure

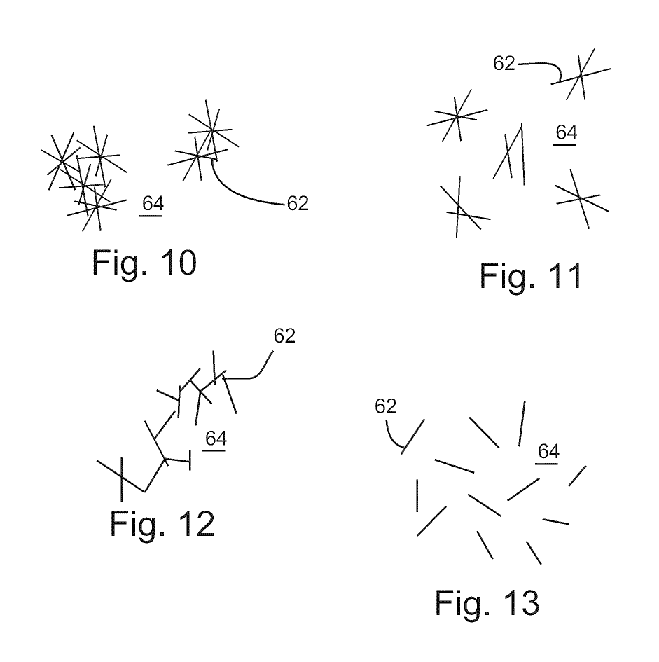

Building a conductive network within an insulative matrix at lower concentration does not necessarily require well distributed filler. However, it does need well dispersed filler, as illustrated in FIGS. 10-13. The FIGS. 10-13 shows the ability of 1D fibers 62 in percolating a 2D plane based on different dispersion and distribution scenarios. The fibers are shown within a matrix material 64. The number of fibers shown is not enough to perfectly percolate the 2D structure. FIGS. 10 and 11 show that the poor dispersion of the fibers 62 prohibits network formation, while sketch FIG. 13 shows that perfect distribution of well dispersed fibers 62 increases the gap between the fibers 62. Only the preferential segregated distribution, FIG. 12, of well dispersed fibers 62 forms a conductive 2D network. A segregated network, such as shown in FIG. 12, has a collection of nanowires in a matrix material with bad distribution and good dispersion.

CuNWs may be synthesized by AC electrodeposition of copper in porous aluminum oxide (PAO) templates. The synthesis of different types of metal nanowires including CuNWs using the AC deposition has been previously reported in the field and will not be described here.

### Polystyrene

Polystyrene (Styron 666D, Mwt 200,000 g/mol, MFI 7.5, Tg 100° C.) powder may be prepared by feeding PS pellets into a Brinkman cutter having a 1.5 mm mesh. The pellets were slowly added and liquid nitrogen was frequently added to cool down the machine. The powder was then collected and separated using a 200 μm sieve. Powder with diameter less than 200 μm was used to prepare the composites by dry mixing.

### Poly(Methyl Methacrylate)

In one embodiment, the matrix material 16 may be Poly(methyl methacrylate) (PMMA). Two examples of PMMA/CuNW composites are described below. Electrically conductive nanocomposites were produced using a similar method to that described in our report of invention. The electrical resistivity of the composites was in the 10⁻¹ Ohm·cm range, and the EMI SE in the order of 27-28 dB. These results indicate that nanocomposites with high shielding effectiveness at low concentrations of nanowires can be attained for polymer materials other than polystyrene.

### Example 1

PMMA/CuNW nanocomposite may be prepared as follows. A PMMA (Sigma-Aldrich, Tg=99.0° C., Mw=120,000) solution of 10 mg/ml was prepared in methylene chloride at room temperature. A solution of CuNWs in methanol solution containing 2.9 mg Cu/ml was added to 50 ml of PMMA solution in sequential steps: (1) 25 ml, (2) 25 ml, (3) 25 ml, (4) 25 ml. 120 ml methanol were added in excess for complete precipitation of the nanocomposite. The sample was under magnetic stirring while mixing, and then placed in an ultrasound bath of 135 W Average power and 38.5-40.5 KHz frequency for 30 seconds. The sample was decanted and subsequently dried under room conditions for 16 hours and finally in a vacuum oven at 40° C. for 2 hours. The nanocomposite powder was compression molded in a rectangular mold (0.2 mm thick, 4.2 cm×2.5 cm) at 250° C. and 5000 psi for 30 minutes. The mold was cooled down using tap water and the sample released from the mold for characterization. The volume electrical resistivity of the composite was 1.77×10⁻¹ Ohm·cm. The average EMI SE in the X-Band range of frequency (8.0-12.4 GHz) was 28 dB.

### Example 2

A PMMA/CuNW nanocomposite may be prepared as follows. A PMMA (Sigma-Aldrich, Tg=99.0° C., Mw=120,000) solution of 20 mg/ml was prepared in methylene chloride. CuNWs from a methanol solution containing 3.4 mg/ml was used. CuNW/MeOH solution was added to 50 ml of PMMA solution in sequential steps: (1) 15 ml, (2) 10 ml, (3) 20 ml, (4) 20 ml, (5) 10 ml. 110 ml of methanol were added for complete precipitation of the nanocomposite. The sample was under magnetic stirring while mixing and then placed for 30 seconds in an ultrasound bath of 135 W Average power and 38.5-40.5 KHz frequency. The sample was decanted and subsequently dried under room conditions for 16 hours. The nanocomposite powder was compression molded in a rectangular mold (0.2 mm thick, 4.2 cm×2.5 cm) at 250° C. and 5000 psi for 30 minutes. The mold was cooled down using tap water and the sample released from the mold for characterization. The volume electrical resistivity of the composite was 3.60×10⁻¹ Ohm·cm. The average EMI SE in the X-Band range of frequency (8.0-12.4 GHz) was 27 dB.

### Polyethylene

In one embodiment, the matrix material 16 may be Polyethylene (PE). CuNW/PE composites with different filler concentrations were prepared by hot solution processing technique. 0.4 g of PE were dissolved in 100 ml of xylene at 110° C. using a silicon oil bath. The flask of the PE/xylene solution was placed in a silicone oil bath. 20 ml of 2.2, 2.8 and 4 mg/ml of CuNW/methanol solution were added to the hot PE/xylene solution under magnetic stirring. At the end of the CuNW/methanol solution addition, the sample was mixed for additional 5 min. The flask containing the composite mixture was taken out of the silicone oil bath and cooled to 40° C.; first by natural convection and then by placing it in a water bath at room temperature. The composite was then separate from the solution by vacuum filtration followed by drying in a vacuum oven at 50° C. for 16 hours. The dried composite was compression molded in a rectangular mold (0.2 mm thick, 4.2 cm×2.5 cm) at 250° C. and 5000 psi for 30 minutes. The mold was cooled down using tap water and the sample released from the mold for characterization.

Metal nanowires can be very competitive to current and alternate EMI shielding technologies. Metals are preferred and promising materials for the development of high performance EMI shielding compounds. Mixtures of two solvents are used to promote nanowire-polymer mixing and composite precipitation. Composites with high concentration of metal nanowires (masterbatch) can be prepared and subsequently processed by conventional techniques like melt mixing and compression molding. Polymer matrix compounds using PS, PC, ABS and their blends containing metal nanowires such as Cu, Ag, Fe, and Ni can be produced.

Immaterial modifications may be made to the embodiments described here without departing from what is covered by the claims.

In the claims, the word “comprising” is used in its inclusive sense and does not exclude other elements being present. The indefinite article “a” before a claim feature does not exclude more than one of the feature being present. Each one of the individual features described here may be used in one or more embodiments and is not, by virtue only of being described here, to be construed as essential to all embodiments as defined by the claims.

1. An electromagnetic interference shield, comprising:
a matrix material; and
a conductive network of nanowires having a segregated distribution of nanowires within the matrix material.

2. The electromagnetic interference shield of claim 1 in which the conductive network of nanowires comprises a honeycomb structure.

3. The electromagnetic interference shield of claim 1 in which the matrix material comprises a polymer.

4. The electromagnetic interference shield of claim 3 in which the polymer comprises polystyrene.

5. The electromagnetic interference shield of claim 1 in which the nanowires comprise metal nanowires.

6. The electromagnetic interference shield of claim 5 in which the metal nanowires comprise copper nanowires.

7. A method of providing an electromagnetic interference shield, comprising:
producing a composition of conductive nanowires and a matrix material;
forming pockets of matrix material in the composition of conductive nanowires and the matrix material to form a conductive network of conductive nanowires within the matrix material; and
locating the conductive network adjacent a source of electromagnetic radiation or adjacent an electromagnetically sensitive electronic device.

8. The method of claim 7 in which mixing a composition of conductive nanowires and the matrix material further comprises mixing the composition of conductive nanowires and the matrix material in a solvent.

9. The method of claim 8, in which forming pockets of matrix material in the composition of conductive nanowires and the matrix material comprises precipitating matrix material from the solvent to form nanowire composite particles.

10. The method of claim 9 further comprising:
separating the nanowire composite particles from the solvent; and
combining the nanowire composite particles into a honeycomb network.

11. The method of claim 10 in which combining the nanowire composite particles into the honeycomb network further comprises using compression molding to combine the nanowire composite particles into the honeycomb network.

12. The method of claim 7, in which forming pockets of polymers in the composition of conductive nanowires and the matrix material comprises dry-mixing the composition of conductive nanowires and the matrix material with additional matrix material.

13. The method of claim 7 in which the conductive nanowires comprise metal nanowires.

14. The method of claim 13 in which the metal nanowires comprise copper nanowires.

15. The method of claim 7 in which the matrix material comprises a polymer.

16. The method of claim 15 in which the polymer comprises polystyrene.

17. A method of forming an electromagnetic shielding material, comprising:
forming a mixture of conductive nanowires and a matrix material in a solvent;
precipitating matrix material from the solvent to form nanowire composite particles;
separating the nanowire composite particles from the solvent; and
combining the nanowire composite particles into a conductive network composition of nanowire and matrix material.

18. The method of claim 17 in which the conductive nanowires comprise metal nanowires.

19. The method of claim 17 in which the matrix material comprises a polymer.

20. (canceled)

21. (canceled)

22. (canceled)

23. (canceled)

24. (canceled)

25. (canceled)

26. (canceled)

27. The electromagnetic interference shield of claim 1 in combination with a housing and a source of electromagnetic radiation, the electromagnetic interference shield being supported by the housing.

28. The combination of claim 27 in which the source of electromagnetic radiation is disposed within the housing.

29. The electromagnetic interference shield of claim 1 in combination with a housing and an electromagnetically sensitive electronic device, the electromagnetic interference shield being supported by the housing.
